(19) United States
(12) Patent Application Publication
(10) Pub. No.: US 2012/0268147 A1
(43) Pub. Date: Oct. 25, 2012

(54) STRUCTURE FOR MEASURING BUMP RESISTANCE AND PACKAGE SUBSTRATE COMPRISING THE SAME

(76) Inventors: Chih CHEN, Hsinchu City (TW); Yuan-Wei Chang, New Taipei City (TW)

(21) Appl. No.: 13/243,927

(22) Filed: Sep. 23, 2011

(30) Foreign Application Priority Data
Apr. 22, 2011 (TW) 100114142

(51) Int. Cl. G01R 27/14

(52) U.S. Cl. 324/713

(57) ABSTRACT

A structure for measuring bump resistance and a package substrate comprising the same are disclosed, the structure for measuring bump resistance of the present invention comprises: plural connecting bumps arranged in a row; at least one first connecting element; and at least one second connecting element; wherein the nth connecting bump and the (n+1)th connecting bump connect by the first connecting element, the (n+1)th connecting bump and the (n+2)th connecting bump connect by the second connecting element, n is an odd number of 1 or more; the first connecting element connects with a first voltage-measurement pad; the second connecting element connects with an auxiliary pad, the auxiliary pad connects with an auxiliary bump, a second voltage-measurement pad connects with the auxiliary bump.

### CROSS REFERENCE TO RELATED APPLICATION

This application claims the benefits of the Taiwan Patent Application Serial Number 100114142, filed on Apr. 22, 2011, the subject matter of which is incorporated herein by reference.

### BACKGROUND OF THE INVENTION

1. Field of the Invention

The present invention relates to a structure for measuring bump resistance and a package substrate comprising the same and, more particularly, to a structure comprising a Kelvin structure and a daisy-chain structure for measuring bump resistance and a package substrate comprising the same.

2. Description of Related Art

For electrical devices, defects such as void formation has been monitored by the change in resistance, whereas resistance measurement is mostly used and is the most direct way to get the resistance coefficient during electromigration of bumps in a package substrate.

For the measurement of resistance, a Kelvin structure or so called the four-point probe structure is usually used. As shown in FIG. 1, the resistance of an object 10 can be obtained by using four probes 11,12,13,14, in which the probes 13,14 provide electrical current and probes 11,12 are used for measuring voltages V1, V2.

Meanwhile, since electromigration in flip-chip solder joints has become an important reliability issue due to the high-density and high-performance requirements, in 2006, the inventor of the present application (Chih Chen et al.) developed a flip-chip solder joints structure using the Kelvin structure and therefore the void nucleation during electromigration as well as the change in resistance can be monitored.

Reference with FIG. 2, when applying the Kelvin probes into the flip-chip solder joints structure for monitoring the change of resistance, each of the connecting bumps B1, B2 may be provided with an auxiliary bump B1′, B2′ and voltage-measurement pads P1, P1′, P2, P2′. When measuring the resistance, for example, a current I1 is provided to the connecting bump B1 and output from the auxiliary bump B1′, whereas the electrical voltages V1⁺, V1⁻ are measured via pads P1, P1′ respectively, and the resistance R1 of the connecting bump B1 can be calculated as the formulae below:

ΔV1=V1⁺−V1³¹ ;

R1=ΔV1/I1.

While measuring the resistance R2 of the connecting bump B2, a current I2 is provided to the connecting bump B2 and output from the auxiliary bump B2′, whereas the electrical voltages V2⁺, V2⁻ are measured via pads P2, P2′ respectively, and the resistance R2 can be calculated as the formulae below:

ΔV2=V2⁺−V2⁻;

R2=ΔV2/I2.

In this flip-chip solder joints structure, many electrical elements (i.e. auxiliary bumps, pads, wires) are needed and applied to obtain the resistance. For example, if n of solder bumps are measured, it should be provided with n of auxiliary bumps, 2n of pads, and 2n of current-input wires. However, although it may precisely measure the resistance of a single bump, the resistance of the macro structure as well as the whole flip chip package structure may not be able to be monitored. Also, the change of resistance can only be monitored on a single joint, other changes as other elements are beyond the measuring scope. In addition, such structure with Kelvin probes may not be able to apply to examine different flip-chip package structures at the same time. That is, each testing sample should be equipped with a new set of Kelvin probes to monitor the change of resistance, but undesirably the testing cost may be greatly increased.

Therefore, there is a present need to provide a structure for measuring bump resistance, which should enable monitoring the change of resistance at each connecting bump and the change of resistance for a macro structure as well as the whole flip chip package structure simultaneously, enable to reduce the number of auxiliary bumps and current-input wires, enable to reduce the area of the test samples, enable to reduce the testing cost, enable to reduce the difficulty for alignment, enable to reduce the manufacturing cost of testing samples, and enable to reduce the tact-time for optimization of parameters, and therefore the efficiency of analysis for the present package and testing field can be improved.

### SUMMARY OF THE INVENTION

Therefore, the present invention provides a structure for measuring bump resistance, which comprises: plural connecting bumps arranged in a row; at least one first connecting element; and at least one second connecting element; wherein the nth connecting bump and the (n+1)th connecting bump are connected by the first connecting element, the (n+1)th connecting bump and the (n+2)th connecting bump are connected by the second connecting element, and n is an odd number of 1 or more (e.g. n=1,3,5, . . . etc); the first connecting element connects with a first voltage-measurement pad; the second connecting element connects with an auxiliary pad, the auxiliary pad connects with an auxiliary bump, and a second voltage-measurement pad connects with the auxiliary bump.

According to the structure for measuring bump resistance of the present invention, when measuring n of connecting bumps for their resistances, only n/2 of auxiliary bumps, n of pads, and a pair of wires are needed. Compared with the structure of prior arts, which needs n of auxiliary bumps, 2n of pads, and 2n of wires to measure n of connecting bumps, the structure for measuring bump resistance of the present invention can reduce half of the auxiliary bumps, pads, and most wires, and therefore many benefits are gained such as that the area of the test samples, the testing cost, the difficulty for alignment, the manufacturing cost of testing samples, and the tact-time for optimization of parameters all can be reduced, and the efficiency of analysis for the package structure and testing field can be improved.

The structure for measuring bump resistance of the present invention is named a Kelvin-daisy composite structure, which combines the Kelvin structure and daisy-chain structure.

Reference with FIG. 3, wherein a daisy-chain structure is shown, the daisy-chain structure comprises plural connecting bumps (i.e. solder bumps) connecting in series, and therefore a resistance of the whole structure can be measured via this structure. The daisy-chain structure is usually applied for the reliability test to measure the total resistance, and the change of the solder joints at the early stage can be monitored. However, due to a large gap between the total resistance of the whole structure and the resistance of each single solder bump (i.e. since the resistance of each single solder bump is much smaller than that of the whole structure), it is difficult to monitor the change precisely for a single solder joint with such daisy-chain structure.

In contrast, the present invention combines the Kelvin structure and the daisy-chain structure thus provides a structure that is called a Kelvin-daisy composite structure, which maintains the original advantages of both structures. According to the Kelvin-daisy composite structure of the present invention, the resistance of each partition for observation can be precisely monitored and analyzed, while the resistance of the whole structure can be measured simultaneously. Therefore, variations such as void nucleation during reliability tests can be precisely detected and positioned by this Kelvin-daisy composite structure.

The Kelvin-daisy composite structure of the present invention is constructed by inserting Kelvin structures with pads (for voltage measurement) in-between solder joints which are connected in a daisy chain structure, and therefore the resistance of each solder bump can be precisely measured and the resistance of the whole structure can be measured simultaneously. Hence, different resistance coefficients due to the void nucleation during electromigration of bumps in a package substrate can be monitored by using the Kelvin-daisy composite structure of the present invention, which has reduced number of auxiliary bumps, pads, and wires. The Kelvin-daisy composite structure of the present invention has the advantage that the area of the test samples, the testing cost, the difficulty for alignment, the manufacturing cost of testing samples, and the tact-time for optimization of parameters can be reduced, and the efficiency of analysis for the present package and testing field can be improved.

According to the structure for measuring bump resistance of the present invention, the first and/or second connecting element can be a metallic wire or metallic pad or any element that can electrically connect those connecting bumps.

According to the structure for measuring bump resistance of the present invention, for example, the connecting bumps are preferably used to connect semiconductor chips with a substrate (e.g. a substrate having wiring layers).

According to the structure for measuring bump resistance of the present invention, the connecting bump and/or the auxiliary bump is preferably a solder bump.

According to the structure for measuring bump resistance of the present invention, the first connecting element, the first voltage-measurement pad, and/or the second voltage-measurement pad preferably locates on a surface of a printed circuit board.

According to the structure for measuring bump resistance of the present invention, the second connecting element preferably locates on a surface of a semiconductor chip such as an IC chip.

The structure for measuring bump resistance of the present invention may preferably further comprise a current-in wire connecting with one end of the row of the connecting bumps; and a current-out wire connecting with the other end of the row of the connecting bumps.

According to the structure for measuring bump resistance of the present invention, the first connecting element and the second connecting element are preferably made of metal such as copper, nickel, or tin.

The present invention also provides a package substrate comprising a structure for measuring bump resistance, the package substrate comprises: a printed circuit board having at least one first connecting element locating on the surface thereof; a chip having at least one second connecting element locating on the surface thereof; and plural connecting bumps arranged in a row; wherein the nth connecting bump and the (n+1)th connecting bump are connected by the first connecting element, the (n+1)th connecting bump and the (n+2)th connecting bump are connected by the second connecting element, and n is an odd number of 1 or more (e.g. n=1,3,5, . . . etc); the second connecting element connects with an auxiliary pad, and the auxiliary pad connects with an auxiliary bump.

According to the package substrate of the present invention, the structure for measuring bump resistance thereof is a structure combining the Kelvin structure and the daisy-chain structure to give a structure called a Kelvin-daisy composite structure, which maintains the original advantages of both structures. The Kelvin-daisy composite structure of the present invention enables monitoring the change of resistance at each connecting bump and the change of resistance for a macro structure as well as the whole flip chip package structure simultaneously, which also enables reducing the numbers of the auxiliary bumps, the current-input wires, the current-output wires, and the pads, and reducing the manufacturing cost of testing samples and the tact-time for optimization of parameters, and therefore the efficiency of analysis for the package and testing field can be improved.

The package substrate of the present invention may preferably further comprise a first voltage-measurement pad connecting with the first connecting element.

The package substrate of the present invention may preferably further comprise a second voltage-measurement pad connecting with the auxiliary bump.

According to the package substrate of the present invention, wherein the connecting bump is preferably a solder bump.

According to the package substrate of the present invention, wherein the auxiliary bump is preferably a solder bump.

According to the package substrate of the present invention, wherein the first voltage-measurement pad and/or the second voltage-measurement pad locates on a surface of the printed circuit board.

The package substrate of the present invention may preferably further comprise a current-in wire connecting with one end of the row of the connecting bumps; and a current-out wire connecting with the other end of the row of the connecting bumps.

According to the package substrate of the present invention, wherein the first connecting element and/or the second connecting element are preferably made of metal such as copper, nickel, or tin.

Other objects, advantages, and novel features of the invention will become more apparent from the following detailed description when taken in conjunction with the accompanying drawings.

### BRIEF DESCRIPTION OF THE DRAWINGS

FIG. 1 is a schematic view of a conventional four-point probe structure;

FIG. 2 is a schematic view of a structure when applying a conventional Kelvin probes into the flip-chip solder joints structure;

FIG. 3 is a schematic view of a daisy-chain structure of the present invention;

FIG. 4 is a schematic view of a structure for measuring bump resistance of the example 1 of the present invention;

FIG. 5 is a schematic view of a structure for measuring bump resistance of the example 2 of the present invention; and

FIG. 6 is a cross-sectional view at the line X-X′ shown in the FIG. 5.

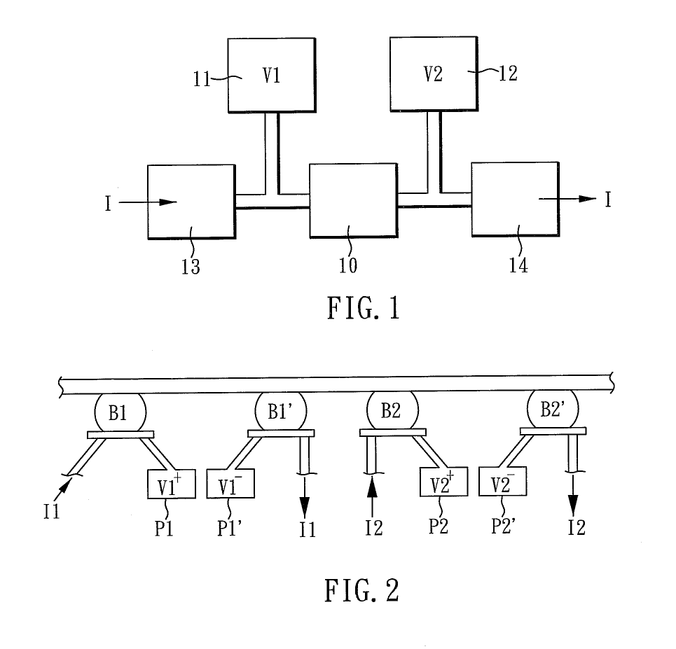

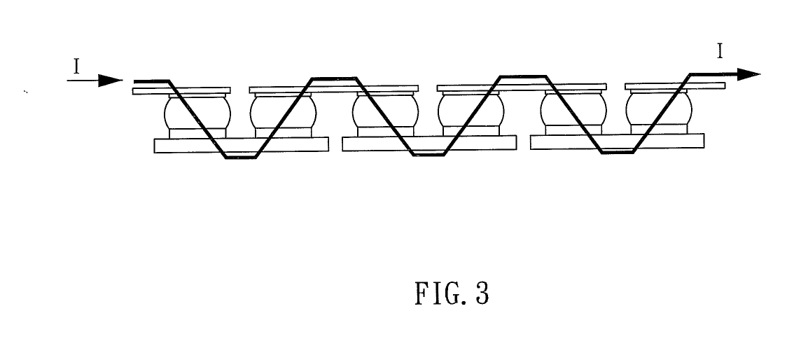

### DETAILED DESCRIPTION OF THE PREFERRED EMBODIMENT

### Example 1

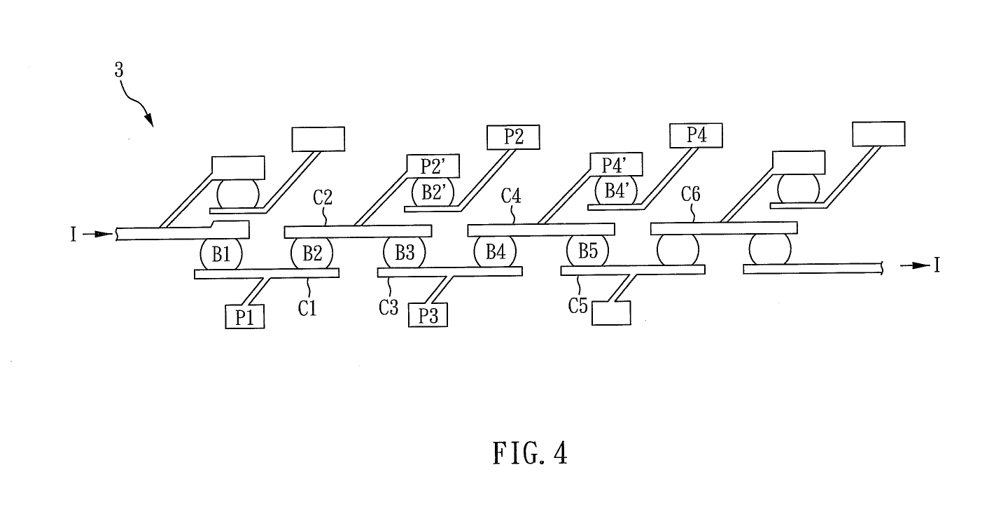

Reference with FIG. 4, a structure 3 for measuring bump resistance of the present example is shown, which comprises: the first to the fifth solder bumps B1-B5 arranged in a row; first connecting elements C1,C3,C5; and second connecting elements C2,C4,C6. The first solder bump B1 and the second solder bump B2 are connected by the first connecting element C1. The second solder bump B2 and the third solder bump B3 are connected by the second connecting element C2. The first connecting element C1 connects with a first voltage-measurement pad P1, the second connecting element C2 connects with an auxiliary pad P2′, the auxiliary pad P2′ connects with an auxiliary bump B2′, and a second voltage-measurement pad P2 connects with the auxiliary bump B2′.

The third solder bump B3 and the fourth solder bump B4 are connected by the first connecting element C3, the fourth solder bump B4 and the fifth solder bump B5 are connected by the second connecting element C4, the first connecting element C3 connects with a first voltage-measurement pad P3, the second connecting element C4 connects with an auxiliary pad P4′, the auxiliary pad P4′ connects with an auxiliary bump B4′, and a second voltage-measurement pad P2 connects with the auxiliary bump B4′.

A current I is input into the left hand side and output from the right hand side of the structure 3.

When measuring the resistance R2 of the second solder bump B2, the voltages V1, V2 are first measured via the first and the second voltage-measurement pads P1 and P2 respectively, and the resistance R2 is then calculated by the formulae below:

ΔV2=V2−V1;

R2=ΔV2/I

Alternatively, when measuring the resistance R3 of the third solder bump B3, the voltages V3, V2 are measured via the third and the second voltage-measurement pads P3 and P2 respectively, and the resistance R3 is then calculated by the formulae below:

ΔV3=V3−V2;

R3=ΔV3/I

According to the present invention, each pair of adjoining bumps are connected by a connecting element, and therefore form a daisy-structure. The Kelvin structures with pads are connected with those connecting elements, that is, the Kelvin structures are inserted in the daisy-structure between solder joints connected by connecting elements.

It should be noted that the structure of the present invention can be expanded and is not limited to the structure shown in FIGS. 4-6.

The present invention combines the Kelvin structure and the daisy-chain structure thus provides a structure that is called a Kelvin-daisy composite structure, which maintains the original advantages of both structures. According to the Kelvin-daisy composite structure (i.e. the structure for measuring bump resistance) of the present invention, the number of the auxiliary bumps, pads, and wires can be reduced, and therefore many benefits are gained, for example, the dimension of the testing samples, the testing cost, the difficulty for alignment, the manufacturing cost of testing samples, and the tact-time for optimization of parameters can be reduced, and the efficiency of analysis for the package structure and testing field can be improved.

### Example 2

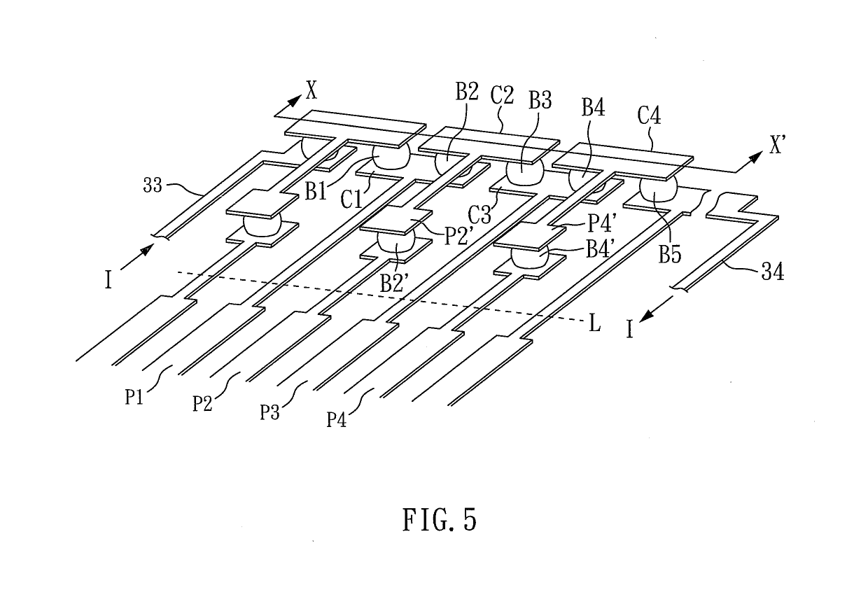

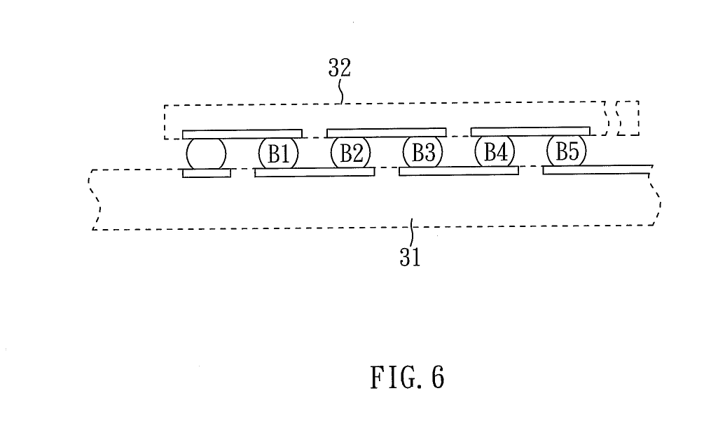

Reference with FIG. 5, a structure for measuring bump resistance of the present example is shown. The FIG. 6 is a cross-sectional view at the line X-X′ shown in the FIG. 5. As shown in FIGS. 5 and 6 of the present example, the auxiliary bumps B2′ and B4′, the first voltage-measurement pads P1 and P3, the second voltage-measurement pads P2 and P4 locate at the same side to the solder bumps B1-B5. The first connecting elements C1 and C3, the first voltage-measurement pads P1 and P3, and the second voltage-measurement pads P2 and P4 locate on the surface of the printed circuit board 31, as shown in FIG. 6. The second connecting elements C2 and C4 locate on the surface of the semiconductive chip 32, as shown in FIG. 6. Those solder bumps B1-B5 locate between the first connecting elements and the second connecting elements, which also means the solder bumps B1-B5 locate between the semiconductive chip 32 and the printed circuit board 31.

When measuring the resistances, a current is input to a current-in wire 33 located at the left-hand side of the solder bumps B1-B5 and is output from the current-out wire 34 located at the right-hand side of the solder bumps B1-B5. The voltages are obtained at the first voltage-measurement pads P1 and P3 and the second voltage-measurement pads P2 and P4, and the resistances are calculated by the same formulae of the example 1. Afterwards (i.e. after a reliability test or a resistance measurement), the first voltage-measurement pads P1 and P3 and the second voltage-measurement pads P2 and P4 can be cut-off from the package substrate by cutting at the cutting line L, and therefore the volume (i.e. the diameter/dimension) of the package substrate can be decreased.

The present invention combines the Kelvin structure and the daisy-chain structure to give a structure called a Kelvin-daisy composite structure for measuring bump resistance and a package substrate comprising the Kelvin-daisy composite structure. The Kelvin-daisy composite structure is advantageous in that statistical analysis results and early-variation results of the testing samples are available, and the resistance of the partition for observation can be precisely monitored and analyzed. The variation during reliability testing can be precisely positioned by the Kelvin-daisy composite structure of the present invention. With the parametric structure design, the tact-time for reliability testing will be reduced significantly, and the dimension and the cost of test samples are reduced simultaneously.

According to the structure for measuring bump resistance of the present invention, when measuring n of connecting bumps for their resistances, only n/2 of auxiliary bumps, n of pads, and a pair of wires are needed. Compared with the structure of prior arts, which needs n of auxiliary bumps, 2n of pads, and 2n of wires to measure n of connecting bumps, the structure for measuring bump resistance of the present invention can reduce the number of the auxiliary bumps, pads, and wires, and therefore many benefits are gained such as that the area of the test samples, the testing cost, the difficulty for alignment, the manufacturing cost of testing samples, and the tact-time for optimization of parameters can be reduced, and the efficiency of analysis for the package structure and testing field can be improved.

As mentioned above, the structure for measuring bump resistance and/or the package substrate of the present invention is advantageous in that statistical analysis results and early-variation results of the testing samples are available, and the resistance of the partition for observation can be precisely monitored and analyzed. The variation during reliability testing can be precisely positioned by the Kelvin-daisy composite structure of the present invention. With the parametric structure design, the tact-time for reliability testing will be reduced significantly, and the dimension and the cost of test samples are reduced simultaneously.

Although the present invention has been explained in relation to its preferred embodiment, it is to be understood that many other possible modifications and variations can be made without departing from the spirit and scope of the invention as hereinafter claimed.

What is claimed is:

1. A structure for measuring bump resistance, which comprises:
plural connecting bumps arranged in a row;
at least one first connecting element; and
at least one second connecting element;
wherein the nth connecting bump and the (n+1)th connecting bump are connected by the first connecting element, the (n+1)th connecting bump and the (n+2)th connecting bump are connected by the second connecting element, and n is an odd number of 1 or more;
the first connecting element connects with a first voltage-measurement pad;
the second connecting element connects with an auxiliary pad, the auxiliary pad connects with an auxiliary bump, and a second voltage-measurement pad connects with the auxiliary bump.

2. The structure for measuring bump resistance as claimed in claim 1, wherein the connecting bump is a solder bump.

3. The structure for measuring bump resistance as claimed in claim 1, wherein the auxiliary bump is a solder bump.

4. The structure for measuring bump resistance as claimed in claim 1, wherein the first connecting element locates on a surface of a printed circuit board.

5. The structure for measuring bump resistance as claimed in claim 1, wherein the second connecting element locates on a surface of a semiconductor chip.

6. The structure for measuring bump resistance as claimed in claim 1, wherein the first voltage-measurement pad locates on a surface of a printed circuit board.

7. The structure for measuring bump resistance as claimed in claim 1, wherein the second voltage-measurement pad locates on a surface of a printed circuit board.

8. The structure for measuring bump resistance as claimed in claim 1, further comprising a current-in wire connecting with one end of the row of the connecting bumps; and a current-out wire connecting with the other end of the row of the connecting bumps.

9. The structure for measuring bump resistance as claimed in claim 1, wherein the first connecting element and the second connecting element are made of metal.

10. A package substrate comprising a structure for measuring bump resistance, the package substrate comprises:
a printed circuit board having at least one first connecting element located on the surface thereof;
a chip having at least one second connecting element located on the surface thereof; and
plural connecting bumps arranged in a row;
wherein the nth connecting bump and the (n+1)th connecting bump are connected by the first connecting element, the (n+1)th connecting bump and the (n+2)th connecting bump are connected by the second connecting element, and n is an odd number of 1 or more;
the second connecting element connects with an auxiliary pad, and the auxiliary pad connects with an auxiliary bump.

11. The package substrate as claimed in claim 10, further comprising a first voltage-measurement pad connecting with the first connecting element.

12. The package substrate as claimed in claim 10, further comprising a second voltage-measurement pad connecting with the auxiliary bump.

13. The package substrate as claimed in claim 10, wherein the connecting bump is a solder bump.

14. The package substrate as claimed in claim 10, wherein the auxiliary bump is a solder bump.

15. The package substrate as claimed in claim 11, wherein the first voltage-measurement pad locates on a surface of the printed circuit board.

16. The package substrate as claimed in claim 12, wherein the second voltage-measurement pad on a surface of the printed circuit board.

17. The package substrate as claimed in claim 10, further comprising: a current-in wire connecting with one end of the row of the connecting bumps; and a current-out wire connecting with the other end of the row of the connecting bumps.

18. The package substrate as claimed in claim 10, wherein the first connecting element and the second connecting element are made of metal.
